(19) United States
(12) Patent Application Publication
(10) Pub. No.: US 2024/0201320 A1
(43) Pub. Date: Jun. 20, 2024

(54) METHOD OF DESIGNING RADOME OF RADAR DEVICE, RADOME AND RADAR DEVICE USING THE SAME

(71) Applicant: HL KLEMOVE CORP., Incheon (KR)

(72) Inventor: Yun Su KANG, Gyeonggi-do (KR)

(21) Appl. No.: 18/219,209

(22) Filed: Jul. 7, 2023

(30) Foreign Application Priority Data
Dec. 14, 2022 (KR) 10-2022-0174638

(51) Int. Cl. G01S 7/02; H01Q 1/42

(52) U.S. Cl. CPC G01S 7/027; H01Q 1/42

(57) ABSTRACT

A radome of a radar device is used in a radar device including a substrate body to which a transmission antenna, a reception antenna and a signal processing chip are mounted, and the radome is spaced apart from the substrate body to protect the substrate body. A value of a first design parameter and a value of a second design parameter of the radome are set such that a difference between a first determination parameter in the presence of the radome and a first determination parameterin the absence of the radome, a difference between a second determination parameter in the presence of the radome and a second determination parameter in the absence of the radome, and a difference between a third determination parameter in the presence of the radome and a third determination parameter in the absence of the radome is within first, second and third threshold ranges, respectively.

### CROSS REFERENCE TO RELATED APPLICATION

This application claims priority from Korean Patent Application No. 10-2022-0174638, filed on Dec. 14, 2022, which is hereby incorporated by reference for all purposes as if fully set forth herein.

### TECHNICAL FIELD

Various embodiments of the present disclosure generally relate to a method of designing a radome of a radar device, a radome and a radar device using the same. In particular, some embodiments of the present disclosure relate to a method for designing a radome of a radar device for optimizing a dimension such as a thickness and a distance from an antenna substrate of the radome, which is a cover of the radar device, and a radome and a radar device using the same.

### BACKGROUND

Recently, a driver assistance system (DAS) is widely used, and there is required to acquire accurate target information.

A plurality of vehicle sensors including a vehicle radar device are used to implement the DAS.

Meanwhile, among vehicle sensors, a camera sensor has an advantage of being able to obtain accurate target information, but has a disadvantage in that its use is limited depending on a climatic environment such as nighttime or fog.

However, a vehicle radar device is widely used as a vehicle sensor in that it is relatively free from such limitations due to nighttime or weather conditions.

A radar device mounted on a vehicle may be used as a sensor device for controlling a vehicle. The radar device may transmit electromagnetic waves having a certain frequency, receive a signal reflected from an object, and process the reception signal to perform a function of detecting the position or speed of the object.

A vehicle radar may include one or more transmission antennas and one or more reception antennas, and may acquire target information such as lateral information (azimuth) and a distance of a target from a mixing signal of a transmission signal and a reception signal reflected from a target.

When designing a radome of the radar device, a theoretical design value may be used to minimize a reflected wave which is reflected from the radome and propagates in a normal line and to maximize a transmitted wave passing through the radome.

A radar for a vehicle is a sensor for detecting a wide azimuth angle rather than the normal direction, and since the radar transmission/reception signal propagates in a wide azimuth range, the radome designed based on the electromagnetic wave in the normal direction has a difference from the theoretical performance.

In particular, in a bistatic structure in which a transmission unit (i.e., transmission antenna) and a reception unit (i.e., receiving antenna) are separated from each other, the error of such a radome design may have a greater effect on the performance of the radar device.

Accordingly, depending on the design of the radome, the operating field of view (FOV) of the radar device may be deteriorated and unwanted side lobes may be generated.

Therefore, in order to minimize the distortion caused by the radome and to maintain the best performance of the vehicle radar device, there is required to optimally ditermine the radome design value (thickness, distance from the substrate, etc.) of the vehicle radar device having wide-angle transmission/reception characteristics.

### SUMMARY

Various embodiments of the present disclosure are to provide a method for designing a radome of a radar device capable of maintaining higher performance of a vehicle radar device, and a radome and radar device manufactured using the same.

Some embodiments of the present disclosure may provide a method for designing a radome of a radar device capable of optimally determining design values (e.g. thickness, distance from substrate, etc.) of the radome of the radar device with wide-angle transmission and reception characteristics, and a radome and radar device manufactured using the same.

Certain embodiments of the present disclosure may provide a method for designing a radome of a radar device capable of determining parameters for designing the radome in order to determine the thickness of the flat radome and the distance of the radome from the substrate using first to third determination parameters indicating characteristics associated with the radome, and a radome and radar device manufactured using the same.

In accordance with an aspect of the present disclosure, there is provided a method for designing a radome which protects a substrate body by being spaced apart from the substrate body on which a transmission antenna, receiving antenna and signal processing chip are mounted. A mathod for designing a radome may include (i) defining a first design parameter and a second design parameter of the radome, (ii) defining a first determination parameter, a second determination parameter, and a third determination parameter indicating distortion characteristics of a transmission signal or a reception signal by the radome, (iii) determining, while changing the values of the first design parameter and the second design parameter within a first design range and a second design range, respectively, a first difference value, a second difference value and a third difference value which are difference values between a first value in the case that the radome is present and a second value in the case that the radome is not present, for each of the first determination parameter, the second determination parameter and the third determination parameter, respectively, and (iv) determining values of the first design parameter and the second design parameter in the case that the first difference value, the second difference value, and the third difference value are included within a first threshold range, a second threshold range and a third threshold range, respectively, as final design parameter values of the radome.

The first design parameter may be a thickness of the radome, and the second design parameter may be a distance between one side of the radome and the substrate body.

In addition, the first determination parameter may be a central peak power of a 2-way transmission/reception signal defined by at least one of the transmission signal and the reception signal, the second determination parameter may be a beam width of the 2-way transmission/reception signal, and the third determination parameter may be a beam error within a filed of view.

More particularly, the second determination parameter may be a 20 dB beam width of the 2-way transmission/reception signal, and the third determination parameter may be a root mean square error (RMSE) of signal power at radiation angles of −40 degrees and +40 degrees.

A mathod for designing a radome according to an embodiment may further include determining initial values of the first design parameter and the second design parameter based on a permittivity of the radome material and a wavelength of the 2-way transmission/reception signal. In this casd, the first design range and the second design range may be determined based on the initial values of the first design parameter and the second design parameter.

In addition, an initial value of the first design parameter may be determined as an integer multiple of the half wavelength (λg/2) of the 2-way transmission/reception signal propagating inside the radome, and an initial value of the second design parameter may be determined as an integer multiple of the half wavelength (λ0/2) of the 2-way transmission/reception signal propagating in an air area between the radome and the substrate body.

In this case, the first design range of the first design parameter may be determined to be 0.69 to 1.06 times the wavelength (λg) of the 2-way transmission/reception signal propagating inside the radome, and the second design range of the second design parameter may be determined to be 0.89 to 1.15 times the wavelength (λ0) of the 2-way transmission/reception signal propagating in the air area between the radome and the substrate body.

In addition, more specifically, the second determination parameter may be a 20 dB beam width of the 2-way transmission/reception signal, and the third determination parameter may be a root mean square error (RMSE) of signal power at radiation angles of −40 degrees and +40 degrees.

Furthermore, the first threshold range may be 0 to 0.3 dB, the second threshold range may be 0 to 0.3 degrees, and the third threshold range may be 0 to 0.7 dB.

In accordance with another aspect of the present disclosure, there is provided a radome of a radar device, wherein the radome is used in the radar device including a substrate body on which a transmission antenna, a receiving antenna and a signal processing chip are mounted and is spaced apart from the substrate body to protect the substrate body. in this case, a value of a first design parameter and a value of a second design parameter of the radome may be set such that differences of a first determination parameter, a second determination parameter and a third determination parameter depending on the presence or absence of the radome is within a threshold range.

In accordance with another aspect of the present disclosure, there is provided a radar device including a transmission antenna and a receiving antenna, a transceiver configured to transmit a transmission signal through the transmission antenna and receive a reception signal reflected from a target through the receiving antenna, a signal processor configured to process the reception signal to acquire information of the target, a substrate body on which the transmission antenna, the receiving antenna, the transceiver and and the signal processor are mounted, and a radome disposed to be spaced apart from the substrate body by a predetermined distance, wherein a value of a first design parameter and a value of a second design parameter of the radome are set such that differences of a first determination parameter, a second determination parameter and a third determination parameter depending on the presence or absence of the radome is within a threshold range.

Some embodiments of the present disclosure may provide a method for designing a radome of a radar device capable of maintaining higher performance of a vehicle radar device, and a radome and radar device manufactured using the same.

In addition, certain embodiments of the present disclosure may optimally determine design values (for example, but not limited to, a thickness, a distance between a radome and a substrate, etc.) of a radome of a vehicle radar device with wide-angle transmission and reception characteristics, thereby reducing or minimizing the distortion of the transmission/reception signal by the radome.

In addition, some embodiments of the present disclosure may optimally determine radome design parameters of a dimension of a radome, such as the thickness of a flat radome, and the distance between the radome and the substrate using first to third determination parameters, thereby reducing or minimizing the distortion of the transmission and/or reception signal cause by the radome.

### BRIEF DESCRIPTION OF THE DRAWINGS

FIG. 1 illustrates a schematic configuration of a vehicle radar device according to an embodiment of the present disclosure.

FIG. 2 illustrates a signal distortion caused by a radome in a vehicle radar.

FIG. 3 is a flowchart of a method for designing a radome of a radar device according to an embodiment of the present disclosure.

FIG. 4 illustrates signal propagation characteristics in a radar device.

FIG. 5 is a graph for illustrating strengths of a reflection signal and a transmission signal according to a thickness (T) of a radome in a radar device.

FIGS. 6A and 6B are graphs for illustrating a configuration for determining initial values of first and second design parameters of a radome using signal transmission/reflection characteristics in a method for designing a radome of a radar device according to an embodiment of the present disclosure.

FIG. 7 is a diagram for describing a configuration for determining first and second design ranges of a radome in a method for designing the radome of a radar device according to an embodiment of the present disclosure.

FIG. 8 illustrates an example of a first determination parameter and a second determination parameter in a method for designing a radome of a radar device according to an embodiment of the present disclosure.

FIG. 9 illustrates an example of a third determination parameter in a method for designing a radome of a radar device according to an embodiment of the present disclosure.

FIG. 10 is a first graph for illustrating characteristics of a first difference value of a first determination parameter according to values of first and second design parameters in a method for designing a radome of a radar device according to an embodiment of the present disclosure.

FIG. 11 is a second graph for illustrating characteristics of a second difference value of a second determination parameter according to values of first and second design parameters in a method for designing a radome of a radar device according to an embodiment of the present disclosure.

FIG. 12 is a third graph for illustrating characteristics of a third difference value of a third determination parameter according to values of first and second design parameters in a method for designing a radome of a radar device according to an embodiment of the present disclosure.

FIG. 13 is a graph for illustrating first to third conditions in which first to third difference values of first to third determination parameters are within first to third threshold ranges, in a method for designing a radome of a radar device according to an embodiment of the present disclosure.

FIG. 14 is a graph for illustrating final design parameter areas of first and second design parameters satisfying first to third conditions of FIG. 13.

FIG. 15 is a graph for illustrating a performance improvement effect of a radome manufactured by a method for designing a radome of a radar device according to an embodiment of the present disclosure.

FIG. 16 is a functional block diagram of a device for designing a radome according to an embodiment of the present disclosure.

FIG. 17 is a conceptual plan view of a substrate body of a radar device according to an embodiment of the present disclosure.

FIG. 18 illustrates an arrangement relationship between a radome and a substrate body used in a radar device according to an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, exemplary embodiments of the present disclosure will be described in detail with reference to the drawings.

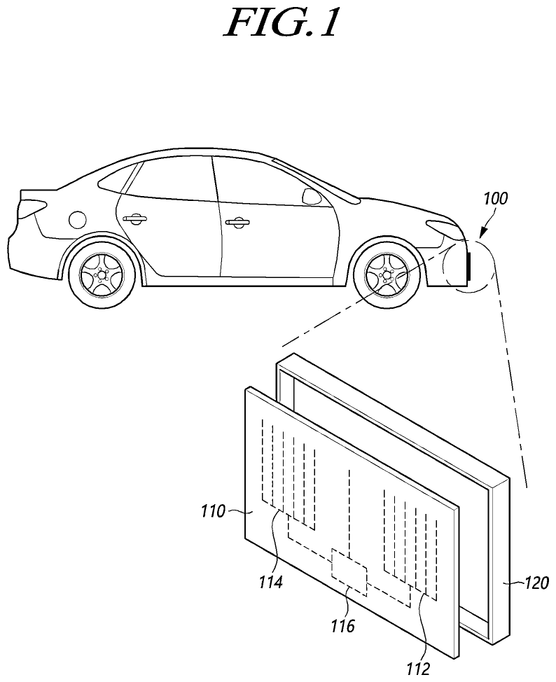

FIG. 1 illustrates a schematic configuration of a vehicle radar device 100 according to an embodiment of the present disclosure.

The radar device 100 according to an embodiment of the present disclosure may be mounted in front of a vehicle to detect one or more objects in front of the vehicle.

The radar device 100 may include a substrate body 110 on which a plurality of transmission antennas 112, a plurality of reception antennas 114 and a signal processing chip or a controller 116 are disposed, and a radome 120 which covers the front of the substrate body 110 to protect components mounted on the substrate body 110.

The signal processing chip 116 of the radar device 100 may control to transmit a transmission signal having a predetermined beam pattern forward using the transmission antenna 112, and receive a reception signal reflected from the object through the reception antenna 114.

The signal processing chip 116 may be configured to acquire information associated with one or more objects around the vehicle, for example, but not limited to, information such as an azimuth angle, distance or range, and relative speed of the object using the reception signal and the transmission signal.

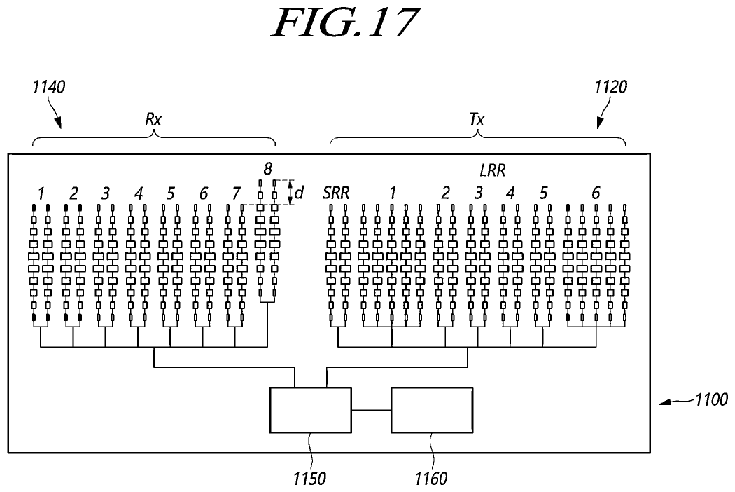

The detailed configuration of such a radar device will be described below in more detail with reference to FIG. 17.

The radome 120 may cover the front of the substrate body 110 to protect components or elements mounted on or to the substrate body 110, and may be made of a non-conductive material having a constant permittivity.

The radome 120 may have various shapes, but a flat radome is generally advantageous in manufacturing and mass production.

In the present disclosure, it will be described a flat radome of a plate shape having a constant thickness as an example. However, the radome 120 can have any shape which can perform one or more functions described in the present disclosure.

The flat radome may be designed to have a specific thickness and a separation distance (spacing) from the substrate body based on electromagnetic waves traveling in a normal line from the antenna to the radome.

In the case of designing a radome, a theoretical design value may be used to minimize a reflection wave reflected from the radome and propagate in a normal line and to maximize a transmission wave passing through the radome.

For example, when designing the radome, the thickness of the radome or the distance (or spacing) from the substrate body may be determined as a multiple of a half-wavelength of the electromagnetic wave in the medium through which the electromagnetic wave propagates.

However, since the vehicle radar is a sensor for detecting a wide azimuth angle rather than a normal direction, and the radar transmission/reception signal propagates in a wide azimuth range, the performance of the radome designed based on the electromagnetic wave in the normal direction may be different from the theoretical performance.

Accordingly, depending on the design of the radome, the operating field of view (FOV) of the radar device may be deteriorated and undesirable side lobes may be generated.

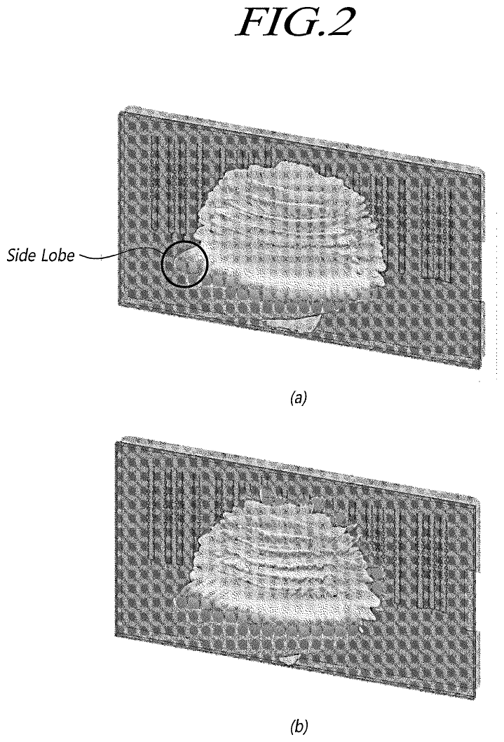

FIG. 2 illustrates a signal distortion caused by a radome in a vehicle radar.

FIG. 2 (a) illustrates a beam pattern of a transmission/reception signal in the case of using a theoretically designed radome. In the beam pattern shown in FIG. 2 (a), undesirable side lobes may be generated on both sides of the beam pattern.

These side lobes may degrade radar signal processing performance, thereby degrading radar object detection performance.

Meanwhile, FIG. 2 (b) illustrates a beam pattern of a transmission/reception signal in the case of using a radome manufactured by a radome design method according to an embodiment of the present disclosure to be described below.

As shown in FIG. 2 (b), in the case of using a radome manufactured by the radome design method according to an embodiment of the present disclosure, a uniform wide-angle beam pattern can be formed by suppressing the side lobe of the beam pattern of the transmission/reception signal.

Accordingly, in order to maintain the optimal performance of the vehicle radar device, there may be required to optimally determine design values (e.g. thickness, distance from the substrate, etc.) of the radome of the vehicle radar device having wide-angle transmission and reception characteristics. Hereinafter, it will be described an exemplary embodiment of a method for designing a radome.

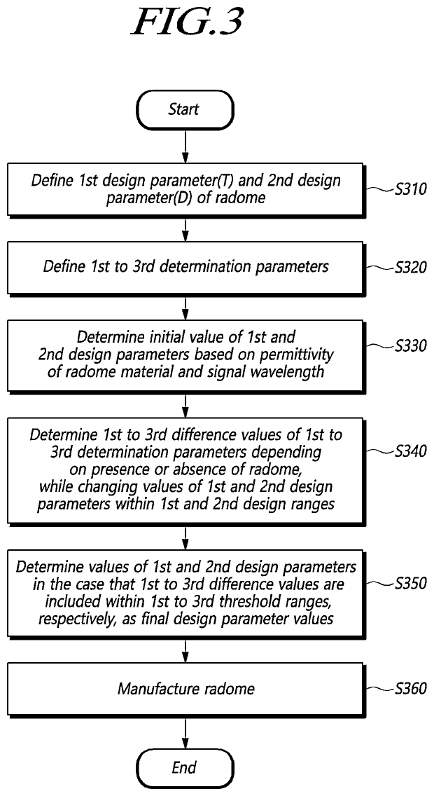

FIG. 3 is a flowchart of a method for designing a radome of a radar device according to an embodiment of the present disclosure.

A method for designing a radome of a radar device according to an embodiment of the present disclosure may include defining a first design parameter and a second design parameter of a radome (Step S310), defining a first determination parameter, a second determination parameter and a third determination parameter indicating distortion characteristics of a transmission signal or reception signal by the radome (Step S320), determining first to third difference values, which are difference values of the first to third determination parameters between a case with the radome and a case without the radome, respectively (Step S340), and determining a value of the first design parameter and a value of the second design parameter as the final design parameter value of the radome based on the first difference value, the second difference value and the third difference value (Step S350).

In addition, the method for designing the radome may further include determining initial values of the first and second design parameters based on a permittivity of the radome material and a signal wavelength (Step S330).

In this case, the first design parameter may be a thickness (T) of the radome, and the second design parameter may be a distance (D) between one side of the radome and the substrate body.

Meanwhile, in the present disclosure, a transmission signal or a reception signal propagating in a space inside the radome or a space between the radome and the substrate may be defined as a 2-way transmission/reception signal. That is, there may be assumed that the radar signal used in the present disclosure is a 2-way signal defined as above, and unless otherwise specified, “signal”, “transmission signal and/or reception signal”, “2-way signal” and “transmission/reception signal” in the present disclosure may refer to 2-way transmission/reception signal defined as above.

In addition, the 2-way signal used in the design of the radome in the present disclosure may be a wide-angle transmission/reception signal in a short-range detection mode. Specifically, if the radome is designed based on the transmission/reception signal of a wide-angle signal in the short-range detection mode, there can also be satisfied the performance of the radome for transmission and reception signals of a narrow-angle signal in the medium-to-long-range detection mode.

The first, second and third determination parameters are parameters representing distortion characteristics of the 2-way transmission/reception signal caused by the radome, and are variables used to determine optimal values of the first and second design parameters.

Specifically, the first determination parameter may be a central peak power P0 of the 2-way transmission/reception signal used in the radar device, that is, a signal peak power at the front where an observation angle is 0 degree.

The second determination parameter may be a beam width of the 2-way transmission/reception signal. For example, the second determination parameter may be a beam width in a state where the central peak power is attenuated with a specific intensity. In this case, the specific attenuation intensity may be 20 dB, and the second determination parameter may be a 20 dB beam width.

In addition, the third determination parameter may be a beam error within a specific field of view (FoV) or a specific viewing angle. For instance, the third determination parameter may be a root mean square error (RMSE) of signal power in a specific radiation angle range or a specific FoV range (e.g., −40 degrees to +40 degrees).

In Step S340 of determining the first difference value, the second difference value and the third difference value, while changing the values of the first design parameter and the second design parameter within a first design range and a second design range, respectively, the first to third difference values which are the differences between a first value when the radome is present and a second value when the radome is not present may be determined for each of the first determination parameter, the second determination parameter and the third determination parameter.

That is, according to the change of the first and second design parameters, the difference between the first value of each of the first to third determination parameters in the case of the presence of the radome and the second value of each of the first to third determination parameters in the case of the absence of the radome may be determined, and the differences between the first values of the first to third determination parameters and the second values of the first to third determination parameters may be determined to be first to third difference values, respectively.

In Step S350 of determining the final design parameter value, a value of the first design parameter and a value of the second design parameter when the first difference value, the second difference value and the third difference value are included within a first threshold range, second threshold range and a third threshold range, respectively, may be determined as the final design parameter value of the radome.

For instance, the first threshold range may be 0 to 0.3 dB, the second threshold range may be 0 to 0.3 degrees, and the third threshold range may be 0 to 0.7 dB.

Meanwhile, in Step S330 of determining the initial values of the first and second design parameters, the initial values of the first and second design parameters may be determined based on the permittivity of the radome material and the wavelength of the signal.

In this case, the first design range and the second design range of the first and second design parameters used in Step S340 of determining the first to third difference values may be determined based on the initial values of the first design parameter and the second design parameter.

An integer multiple of a half wavelength (λg/2) of the transmission signal or reception signal (i.e., 2-way transmission/reception signal) propagating inside the radome may be determined as the initial value of the first design parameter, and an integer multiple of a half wavelength (λ0/2) of the transmission signal or reception signal (i.e., 2-way transmission/reception signal) propagating in an air area between the radome and the substrate body may be determined as the initial value of the second design parameter.

In this case, the first design range of the first design parameter may be determined to be 0.69 to 1.06 times the wavelength (λg) of the transmission signal or reception signal (e.g., 2-way transmission/reception signal) propagating inside the radome. The second design range of the second design parameter may be determined to be 0.89 to 1.15 times the wavelength λ0 of the transmission signal or reception signal (e.g., 2-way transmission/reception signal) propagating in the air area between the radome and the substrate body.

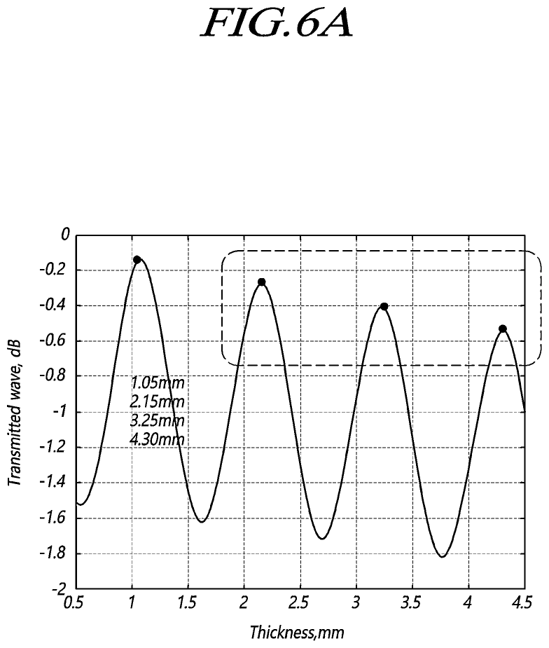

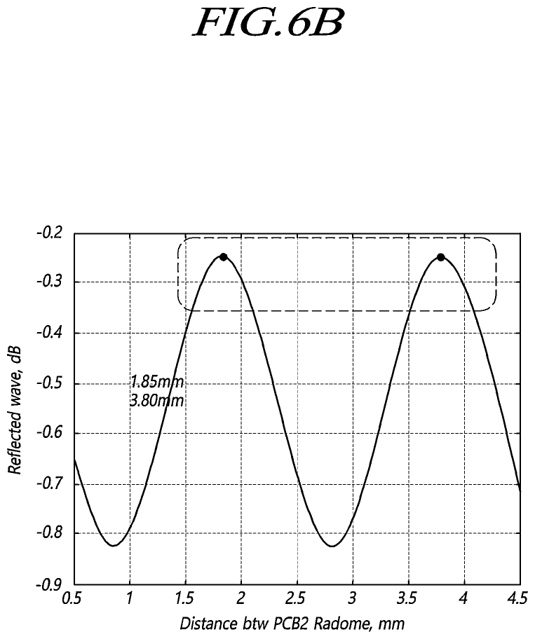

The specific examples of operation or configuration of Steps S310 to S350 will be described below in more detail with reference to FIGS. 6 to 16.

The radome manufactured according to certain embodiments of the present disclosure can optimally determine the design value (e.g. thickness, distance from the substrate, etc.) of the radome of the vehicle radar device having wide-angle transmission and reception characteristics, so that the signal distortion caused by the radome can be minimized in the radar device, thereby improving the object detection performance of the radar device including the radome.

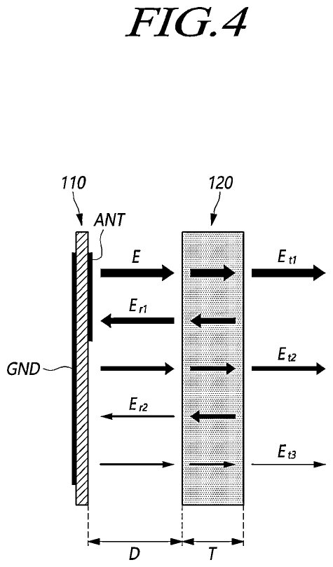

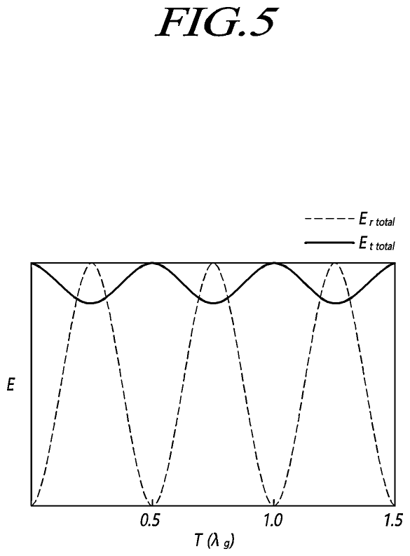

FIG. 4 illustrates propagation signal characteristics in a radar device, and FIG. 5 is a graph for illustrating strengths of a reflection signal and a transmission signal according to a thickness (T) of a radome in a radar device.

A signal radiated from the substrate body 110 of the radar device is expressed as an initial intensity E.

Among the radiation signals, the light incident on the radome in a normal direction is emitted to the outside of the radar device after a specific attenuation occurs while passing through the radome. The intensity of a first transmission signal at this time is expressed as Eₜ₁.

Meanwhile, some of the initial radiation signals may be reflected by the surface of the radome 120 and returned back to the substrate body 110, and the intensity of a first reflection signal is expressed as Eᵣ₁.

The first reflection signal is reflected by the substrate body 110 again, passes through the radome 120, and then is emitted to the outside of the radar device as a second transmission signal. The intensity of this secondary transmission signal is expressed as Eₜ₂.

According to these signal propagation characteristics, the total intensity of the transmission signals passed through the radome 120 and transmitted to the outside of the radar device among the initial radiation signals are expressed as E_{t total}, and the total intensity of the reflection signal trapped between the radome 120 and the substrate body 110 or attenuated in the radome 120 are expressed as E_{r total}.

In order to minimize signal distortion by the radome, the total intensity E_{t total} of the transmission signal should be increased (or maximized) and the total intensity E_{r total} of the reflection signal should be decreased (or minimized).

FIG. 5 is a graph for illustrating a total intensity E_{t total} of a transmission signal and a total intensity E_{r total} of a reflection signal according to the thickness of a radome.

As shown in FIG. 5, the thickness of the radome capable of maximizing the total intensity E_{t total} of the transmission signal and minimizing the total intensity E_{r total} of the reflection signal may be an integer multiple of the half wavelength (λg/2) of the signal passing through the radome.

In addition, the total intensity E_{t total} of the transmission signal and the total intensity E_{r total} of the reflection signal may be changed according to a separation distance D between the surface of the radome 120 and the substrate body 110.

The distance D between the radome 120 and the substrate 110 capable of maximizing the total intensity E_{t total} of the transmission signal and minimizing the total intensity E_{r total} of the reflection signal may be an integer multiple of the half wavelength (λ0/2) of the signal passing through an air space between the radome 120 and the substrate body 110.

Therefore, in the method of designing the radome according to an embodiment of the present disclosure, an initial value of the thickness T of the radome 120, which is the first design parameter, may be determined by an integer multiple of a half-wavelength (λg/2) of a signal propagating inside the radome 120.

In addition, an initial value of the distance D between the radome 120 and the substrate body 110, which is the second design parameter, may be determined by an integer multiple of a half-wavelength (λ0/2) of a signal propagating in the air area.

Meanwhile, in order to determine the initial value of the first design parameter, it is necessary to determine the wavelength λg of the signal propagating inside the radome. The wavelength λg of the signal propagating inside the radome may be determined based on a permittivity or relative permittivity εr of the material constituting the radome in addition to the original signal wavelength λ0.

Therefore, in the method of designing the radome according to an embodiment of the present disclosure, the dielectric constant or relative permittivity εr of the radome may be measured by using the transmission characteristics of the dielectric specimen to be used for the radome.

As an example, it may be assumed that, in the embodiment of the present disclosure, the operating frequency of the signal used by the radar device is 76.5 GHZ, and the dielectric constant or relative permittivity εr of the radome is about 3.31 as a result of measuring the dielectric material constituting the radome.

Therefore, assuming that the operating frequency of the signal used by the radar device is 76.5 GHZ and the dielectric constant or relative permittivity εr of the dielectric constituting the radome is 3.31, the initial values of the first and second design parameters can be determined.

FIGS. 6A and 6B are graphs for illustrating a configuration for determining initial values of first and second design parameters of radome a using signal transmission/reflection characteristics in a method for designing a radome of a radar device according to an embodiment of the present disclosure.

FIG. 6A illustrates the measurement result of an intensity of the transmission signal depending on the thickness T of the radome in the case that the operating frequency of the signal used by the radar device is 76.5 GHZ and the dielectric constant or relative permittivity εr of the dielectric constituting the radome is 3.31. Floquet Port simulation program may be used for this purpose, but is not limited thereto.

A signal of 76.5 GHz is irradiated in a normal direction in a state that only the radome is disposed, and the strength of a transmission wave transmitted through the radome is measured.

As a result, the thickness of the radome capable of maximizing the signal transmission performance of the radome may be 1.05 mm, 2.15 mm, 3.25 mm, 4.30 mm, and the like.

More specifically, in the case that the thickness of the radome is 1.05 mm, the maximun transmission performance is provided, and in the case that the thickness of the radome is 2.15 mm, the next maximum penetration performance is obtained.

Accordingly, as an initial value of the thickness T of the radome, which is the first design parameter, one of 1.05 mm, 2.15 mm, 3.25 mm, and 4.30 mm may be selected.

In terms of performance, it is desirable that the thickness of the radome is 1.05 mm. However, since the radome is required to have specific strength and durability, 1.05 mm may be thin to be adopted for the thickness of the radome. Therefore, in one example, 2.15 mm may be selected as the initial value of the radome thickness T, which is the first design parameter. Alternatively, if stronger durability or the like is required, 3.25 mm or the like may be used as the initial value of the radome thickness T.

FIG. 6B illustrates the result of measuring the intensity of the reflection wave from the substrate according to the distance D between the radome and the substrate in a condition in which the operating frequency of the signal used by the radar device is 76.5 GHZ and the dielectric constant or relative permittivity εr of the dielectric constituting the radome is 3.31.

After the radome and the substrate are separated by the predetermined distance D, a signal is radiated from the substrate to measure the intensity of a reflection wave propagated through air→radome→substrate→GND→substrate→air.

As a result, the distances D between the radome and the substrate capable of maximizing the signal transmission performance of the radome are 1.85 mm, 3.80 mm, and the like.

Accordingly, one of 1.85 mm and 3.80 mm may be selected as an initial value of the radome-to-substrate distance D, which is the second design parameter.

In terms of the design of the radar device, the radome is required to be separated from the substrate body by a certain distance or more. If the distance between the radome and the substrate is 1.85 mm, the substrate and the radome may be too close, and therefore, in one example, 3.80 mm may be selected as an initial value of the distance D between the radome and the substrate, which is the second design parameter.

As described above, if the initial values of the first design parameter and the second design parameter are determined based on the permittivity of the radome material and the wavelength of the transmission signal or the reception signal, the first and second design ranges of the first and second design parameters may be determined based on the initial values of the first and second design parameters.

That is, the first and second design ranges of the first and second design parameters used to determine the difference of the first to third determination parameters between the presence or absence of the radome may be determined.

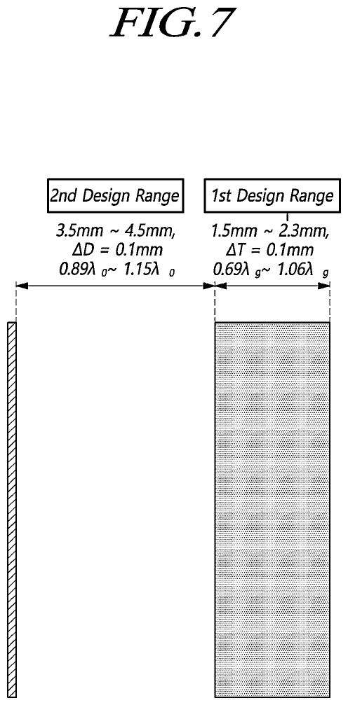

FIG. 7 is a diagram for describing a configuration for determining first and second design ranges of a radome in a method for designing the radome of a radar device according to an embodiment of the present disclosure.

As described in the embodiment of FIG. 6, the initial values of the first design parameter T and the second design parameter D may be determined to be 2.15 mm and 3.80 mm, respectively, and in this case, a first design range of the first design parameter may be set to 1.5 mm to 2.3 mm, that is, 0.69λg to 1.06λg, and the second design range of the second design parameter may be set to 3.5 mm to 4.5 mm, that is, 0.89λ0 to 1.15λ0, but is not limited thereto.

That is, while changing the first design parameter (e.g. a radome thickness T) from 1.5 mm to 2.3 mm by an increment of 0.1 mm, the differences of the first and third determination parameters between the presence and absence of the radome may be determined.

Similarly, while changing the second design parameter (e.g. a distance D between the radome and the substrate) from 3.5 mm to 4.5 mm by an increment of 0.1 mm, the difference of the first to third determination parameters between the presence and absence of the radome may be determined.

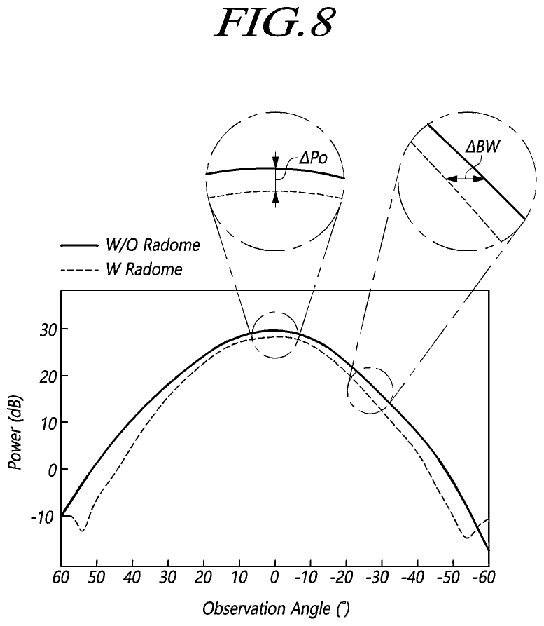

FIG. 8 is a graph for illustrating an example of a first determination parameter and a second determination parameter in a method for designing a radome of a radar device according to an embodiment of the present disclosure.

The first and second determination parameters used in the radome design method of the radar device according to an embodiment of the present disclosure may be the center peak power P0 of the 2-way transmission/reception signal used in the radar device, that is, a signal peak power in the front with 0 degree of the observation angle.

Specifically, as shown in FIG. 8, there may be measured the signal peak power (i.e., power at boresight) P0 at the front in the case of the presence of the radome (dotted line) and in the case of the absence of the radome (solid line).

In addition, while changing the value of the first design parameter within the first design range and changing the second design parameter within the second design range, a first difference value, which is a difference between a front signal peak (i.e., a first value) in the case of the presence of the radome (W Radome; dotted line in FIG. 8) and a front signal peak power (i.e., a second value) in the case of the absence of the radome (W/O Radome; solid line in FIG. 8) can be determined.

In this case, the first difference value ΔPower of the first determination parameter may be calculated as in Equation 1 below.

ΔPower at boresight=|P_{w.o radome}(Anlge=0°)|−|P_{w.radome}(Anlge=)0°| [Equation 1]

In addition, the second determination parameter used in the method of designing the radome of the radar device according to an embodiment of the present disclosure may be a beam width of the 2-way transmission/reception signal. For instance, the second determination parameter may be a beam width of 20 dB.

The left and right azimuth range of the signal attenuated to an intensity of −20 dB from the central peak power, which is the first determination parameter, may be expressed as a −20 dB beam width, and this may be determined as the determination second parameter. This second determination parameter may be expressed as the 20 dB beam width.

In addition, while changing the value of the first design parameter within the first design range and the second design parameter within the second design range, a second difference value, which is a difference between a 20 dB beam width (i.e., a first value) in the case of the presence of the radome (W Radome; dotted line in FIG. 8) and a 20 dB beam width (i.e., a second value) in the case of the absence of the radome (W/O Radome; solid line in FIG. 8) can be determined.

In this case, the second difference value of the second determination parameter may be expressed as a Δ20 dB beam width, and this may be determined as in Equation 2 below.

Δ20 dB Beamwidth=|20 dB Beamwidth_{w.o radome}|−|20 dB Beamwidth_{w.o radome}| [Equation 2]

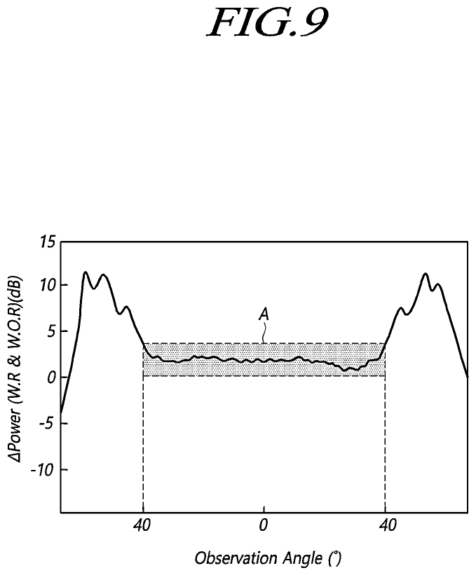

FIG. 9 is a graph for illustrating an example of a third determination parameter in a method for designing a radome of a radar device according to an embodiment of the present disclosure.

The third determination parameter used in the method for designing the radome of the radar device according to an embodiment of the present disclosure may be a beam error within a specific field of view or a viewing angle. For instance, the third determination parameter may be a root mean square error (RMSE) of signal power in a specific field of view range or a viewing angle range (e.g., −40 degrees to +40 degrees).

While changing the value of the first design parameter within the first design range and changing the second design parameter within the the second design range, a third difference value, which is a difference between a signal power (i.e., a first value) in the case of the presence of the radome and a signal power (i.e., a second value) in the case of the absence of the radome.

As an example, as shown in FIG. 9, the root mean square error (RMSE) of the signal power in the case of the presence of the radome and the signal power in the case of the absence of the radome in the viewing angle range of −40 degrees to +40 degrees (area A in FIG. 9) may be determined as the third difference value of the third determination parameter.

In this case, the third difference value of the third determination parameter may be expressed as RMSE_{ϕazimuth±40°}, and this may be determined as in Equation 3 below.

$${RMSE}_{{ϕ}_{azimuth} \pm 40 °} = \sqrt[]{\frac{1}{n} {\sum }_{i = 1}^{n} {( \vert {P}_{w . o radonne} \vert - \vert {P}_{w . radome} \vert )}^{2}} , {ϕ}_{i , azimuth} ∈ [ - 40 ° , 40 ° ] \qquad [ Equation 3 ]$$

As shown in FIGS. 8 and 9, if the first difference value, the second difference value and the third difference value depending on the values of the first design parameter and the second design parameter and the presence or absence of the radome are determined, the first difference value, the second difference value and the third difference value may be databased.

In addition, the first difference value, the second difference value and the third difference value according to the change to the values of the first design parameter and the second design parameter may be expressed as a graph, a second graph, and a third graph, first respectively.

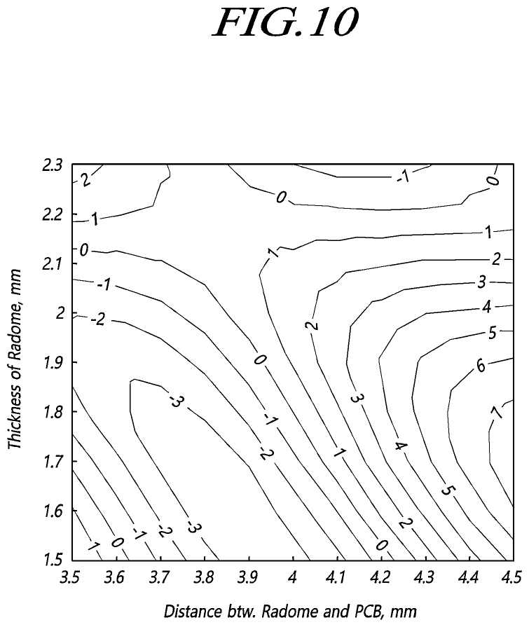

It will be described the first graph, the second graph and the third graph of the first difference value, the second difference value and the third difference value according to the values of the first design parameter and the second design parameter in more detail with reference to FIGS. 10 to 12.

FIG. 10 is a first graph for illustrating characteristics of a first difference value of a first determination parameter according to values of first and second design parameters in a method for designing a radome of a radar device according to an embodiment of the present disclosure.

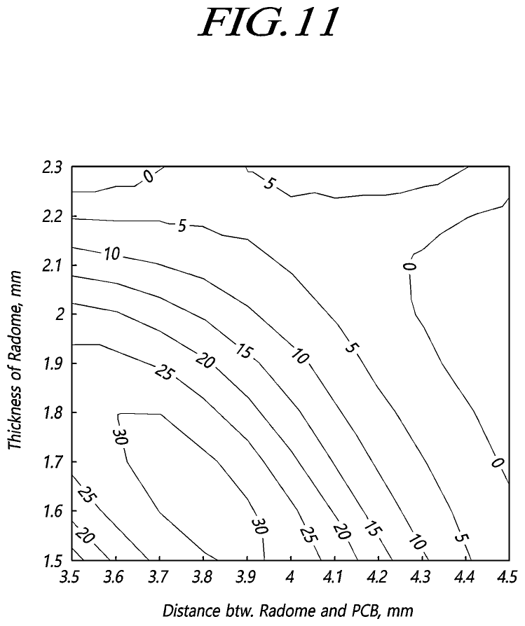

FIG. 11 is a second graph for illustrating characteristics of a second difference value of a second determination parameter according to values of first and second design parameters in a method for designing a radome of a radar device according to an embodiment of the present disclosure.

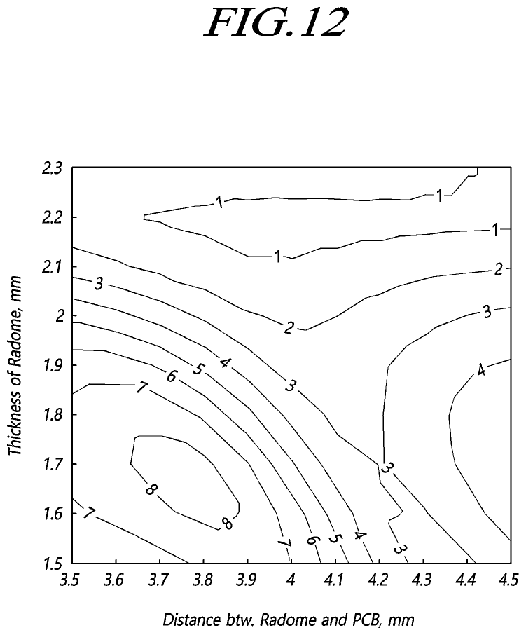

FIG. 12 is a third graph for illustrating characteristics of a third difference value of a third determination parameter according to values of first and second design parameters in a method for designing a radome of a radar device according to an embodiment of the present disclosure.

In the graphs of FIGS. 10 to 12, the X-axis indicates the second design parameter which is the distance D between radome and the substrate, and the Y-axis indicates the first design parameter, which is the thickness T of the radome.

For example, when changing the first design parameter and the second design parameter within the first design range and the second design range, respectively, the first difference value ΔPower of the first determination parameter may be expressed as in the first graph of FIG. 10.

Similarly, when changing the first design parameter and the second design parameter within the first design range and the second design range, respectively, the second difference value (i.e., Δ20 dB beam width) of the second determination parameter may be expressed as the second graph of FIG. 11.

In addition, when changing the first design parameter within the first design range and changing the second design parameter within the second design range, the third difference value (RMSE_{ϕazimuth±40°}) of the third determination parameter may be expressed as the third graph of FIG. 12.

In the first to third graphs of FIGS. 10 to 12, the first to third difference values are expressed in the form of a contour line, and a region in which the first to third difference values are smaller than a predetermined threshold value can be determined.

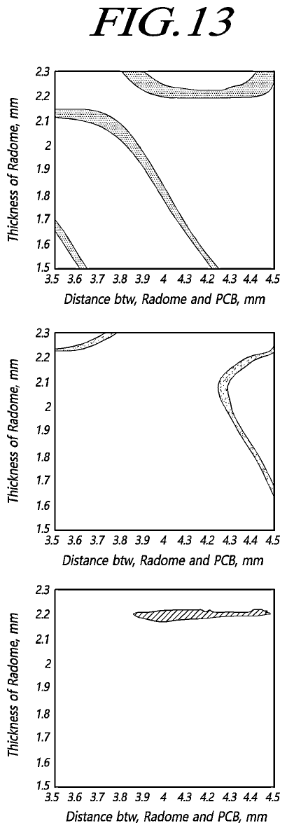

FIG. 13 is a graph for illustrating first to third conditions in which first to third difference values of first to third determination parameters are within first to third threshold ranges, in a method for designing a radome of a radar device according to an embodiment of the present disclosure.

In the first graph of FIG. 13, a first condition region in which the first difference value ΔPower of the first determination parameter is within a first threshold range can be determined. For example, in the first graph of FIG. 13, a first condition region (shaded portion) is a region in which the first difference value ΔPower of the first determination parameter is within the first threshold range of 0 to 0.3 dB.

In addition, in the second graph of FIG. 13, a second condition region in which the second difference value (i.e., Δ20 dB beam width) of the second determination parameter is within a second threshold range can be determined. For example, in the second graph of FIG. 13, a second condition region (shaded portion) is an area in which the second difference value (i.e., Δ20 dB beam width) of the second determination parameter is within the second threshold range of 0 to 0.7°.

Similarly, in the third graph of FIG. 13, a third condition region in which the third difference value RMSE_{ϕazimuth±40°} of the third determination parameter is within a third threshold range can be determined. For example, in the third graph of FIG. 13, a third condition region (shaded portion) is an area in which the third difference value RMSE_{ϕazimuth±40°} of the third determination parameter is within the third threshold range of 0 to 0.7 dB.

As shown in FIG. 13, the final values of the first and second design parameters may be determined based on the first to third condition regions in which the first to third difference values of the first to third determination parameters are equal to or less than a predetermined threshold value.

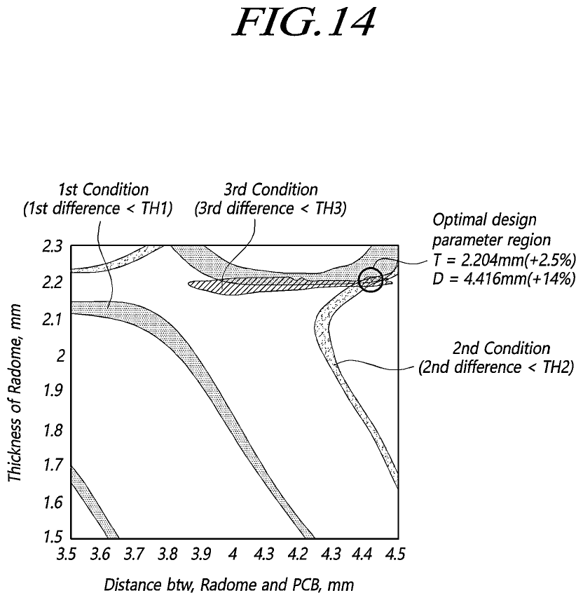

FIG. 14 is a graph for illustrating final design parameter areas of first and second design parameters satisfying the first to third conditions of FIG. 13.

In a method for designing a radome of a radar device according to an embodiment of the present disclosure, a value of the first design parameter and a value of the second design parameter in the case that the first to third difference values of the to third determination parameters are within the first to third threshold ranges may be determined as final design parameter values of the radome.

Specifically, as shown in FIG. 13, first to third condition regions in which the first to third difference values of the first to third determination parameters are equal to or less than a predetermined threshold are determined.

In FIG. 14, an overlapping region of the first to third condition regions in which the first to third difference values of the first to third determination parameters are equal to or less than a predetermined threshold value may be defined as an optimal design parameter region.

Specifically, an overlapping reqion satisfying all of the first condition that the first difference value ΔPower of the first determination parameter is within the first threshold range of 0 to 0.3 dB, the second condition that the second difference value (i.e., 420 dB beam width) of the second determination parameter is within the second thrshold range of 0 to 0.7°, and the third condition that the third difference value RMSE_{ϕazimuth±40°} of the third determination parameter is within the third threshold range of 0 to 0.7 dB may be determined as an optimal design parameter region.

Coordinate values (X, Y) of a specific point in the optimal design parameter region may be determined as final values of the second design parameter and final values of the first design parameter, respectively.

In the embodiment of FIG. 14, the final value Tf of the first design parameter (e.g. the thickness of the radome) may be determined to be 2.204 mm, and the final value Df of the second design parameter (e.g. the distance between the radome and the substrate) may be determined to be 4.416 mm.

As shown in FIG. 6, the initial values (i.e., theoretical values) of the ½ design parameters were 2.15 mm and 3.8 mm, respectively. When a method for designing a radome according to an embodiment of the present disclosure is applied to these initial values, the final values of the first and second design parameters are increased by +0.054 mm (+2.5%) and +0.616 mm (+14%), respectively, compared to the theoretical initial values.

That is, when the method for designing the radome according to an embodiment of the present disclosure is applied, the final values of the first and second design parameters may be increased to a specific extent compared to the theoretical initial values of the first and second design parameters.

Accordingly, by using some embodiments of the present disclosure, it is possible to manufacture a radome and a radar device including the same based on the final first and second design parameters.

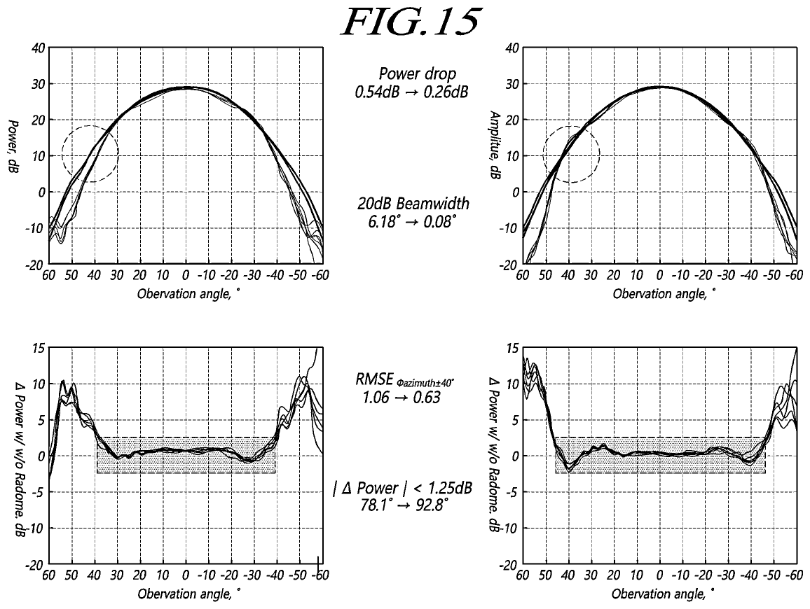

According to a method for designing a radome according to certain embodiments of the present disclosure, the final values of the first and second design parameters may be determined differently from the theoretical initial values, thereby improving the performance of the radar device. These effects will be described in more detail with reference to FIG. 15.

FIG. 15 is graphs for illustrating a performance improvement effect of a radome manufactured by a method of designing a radome of a radar device according to an embodiment of the present disclosure.

The graphs on the left of FIG. 15 illustrate the signal characteristics of the radar device manufactured based on the initial values of the theoretical first and second design parameters, and the graphs on the right of FIG. 15 illustrate the signal characteristics of the radar device manufactured based on the final values of the first and second design parameters determined according to the method for designing the radome according to an embodiment of the present disclosure.

As shown in FIG. 15, compared to the radar device manufactured with the theoretical initial design parameter values, the radar device manufactured according to the method for designing the radome according to an embodiment of the present disclosure can reduce a difference (power drop) of the central peak power P0 with or without the radome from 0.54 dB to 0.26 dB.

In addition, compared to the radar device manufactured with the theoretical initial design parameter values, the radar device manufactured according to the method for designing the radome according to an embodiment of the present disclosure may reduce a difference in 20 dB beam width (i.e., Δ20 dB beam width) depending on the presence or absence of the radome from 6.18 degrees to 0.08 degrees.

In addition, compared to the radar device manufactured with the theoretical initial design parameter values, the radar device manufactured according to the method for designing the radome according to an embodiment of the present disclosure can decrease a beam error RMSE_{ϕazimuth±40°} depending on the presence or absence of the radome from 1.06 to 0.63.

Accordingly, the method for designing the radome according to an embodiment of the present disclosure can reduce a difference of the central peak power P0, a difference in 20 dB beam width (i.e., Δ20 dB beam width) and a beam error RMSE_{ϕazimuth±40°} depending on the presence or absence of the radome, thereby minimizing signal distortion caused by the radome.

Accordingly, the performance degradation of the radar device due to the radome may be reduced or minimized, and as a result, it is possible to increase maximize the detection performance of the radar device.

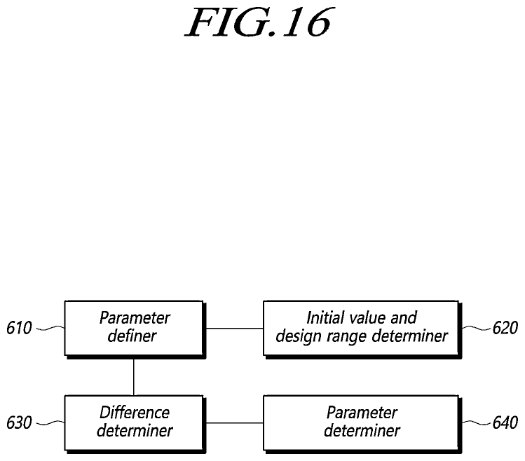

FIG. 16 is a functional block diagram of a device for designing a radome according to an embodiment of the present disclosure.

The device of designing the radome according to an embodiment of the present disclosure may include a parameter definer or parameter defining module 610, a difference determiner or difference determination module 630, and a parameter determiner or parameter determination module 640. Optionally, an initial value and design range determiner or initial value and design range determination module 620 may be further included.

The parameter definer 610 may define a first design parameter for designing the radome and a second design parameter for designing the radome, and may define a first determination parameter, a second determination parameter and a third determination parameter indicating distortion characteristics of the transmission signal or reception signal caused by the radome.

For example, the first design parameter may be a thickness T of the radome, and the second design parameter may be a distance D between one side of the radome and a substrate body. The first determination parameter may be a central peak power P0 of the transmission signal or the reception signal used in the radar device, the second determination parameter may be a beam width of the transmission signal or the reception signal, and the third determination parameter may be a beam error within a specific field of view.

Since the first and second design parameters and the first to third determination parameters correspond to the configuration as described above, detailed descriptions are omitted to avoid duplication.

The initial value and design range determiner 620 may determine the initial values of the first and second design parameters based on the permittivity of the material of the radome and the signal wavelength.

The initial value of the first design parameter may be determined by an integer multiple of the half-wavelength (λg/2) of the transmission signal or reception signal propagating inside the radome, and the initial value of the second design parameter may be determined by an integer multiple of a half wavelength (λ0/2) of the transmission signal or reception signal propagating in an air space between the radome and the substrate body.

The difference determiner 630 may be configured to, while changing the values of the first design parameter and the second design parameter within a first design range and a second design range, respectively, determine a first difference value, a second difference value and a third difference value which are difference values between a first value in the case of the presence of the radome and a second value in the case of the absence of the radome, for each of the first determination parameter, the second determination parameter and the third determination parameter, respectively.

The initial value and design range determiner 620 may determine the first design range and the second design range for the first design parameter and the second design parameter used in the difference determiner 630 based on the initial values of the first design parameter and the second design parameter, respectively.

Specifically, the first design range for the first design parameter may be determined to be 0.69 to 1.06 times the wavelength (λg) of the transmission signal or reception signal propagating inside the radome, and the second design range for the second design parameter may be determined to be 0.89 to 1.15 times the wavelength (λ0) of the transmission signal or reception signal propagating in an air space or area between the radome and the substrate body.

The parameter determiner 640 may determine a value of the first design parameter and a value of the second design parameter as final design parameter values of the radome when the first difference value, the second difference value and the third difference value are within the first threshold range, the second threshold range and the third threshold range, respectively.

For instance, the first threshold range may be 0 to 0.3 dB, the second threshold range may be 0 to 0.3 degrees, and the third threshold range may be 0 to 0.7 dB, but is not limited thereto.

The device of designing the radome and/or one or more components of the device of designing the radome, such as the parameter definer 610, the difference determiner 630, the parameter determiner 640, and the initial value and design range determiner 620, according to an embodiment of the present disclosure may be implemented as an electronic controller unit (ECU), a microcomputer, a processor or the like.

In the present embodiment, a computer system for the device of designing the radome may be implemented as an electronic control unit. The electronic control unit may include at least one or more elements of one or more processors, memories, storage unit, user interface input unit and user interface output unit, which may communicate with each other via a bus. Furthermore, the electronic control unit may also comprise a network interface for connecting to the network. The processor may be a CPU or a semiconductor device that is capable of executing processing instructions or operations stored in memory and/or storage unit. Memory and storage unit may include various types of volatile/non-volatile storage media. For example, memory may include ROM and RAM.

The control device or ECU of the device of designing the radome may include a processor, a storage device such as a memory, and a computer program capable of performing a specific function. In addition, the parameter definer 610, the initial value and design range determiner 620, the difference determiner 630 and the parameter determiner 640 may be implemented as software modules capable of performing respective corresponding functions.

That is, the parameter definer 610, the initial value and design range determiner 620, the difference determiner 630 and the parameter determiner 640 according to embodiments of the present disclosure may be implemented as respective software modules and stored in a memory, and each software module may be executed at a specific time point in an arithmetic processing unit such as an ECU included in a computer device.

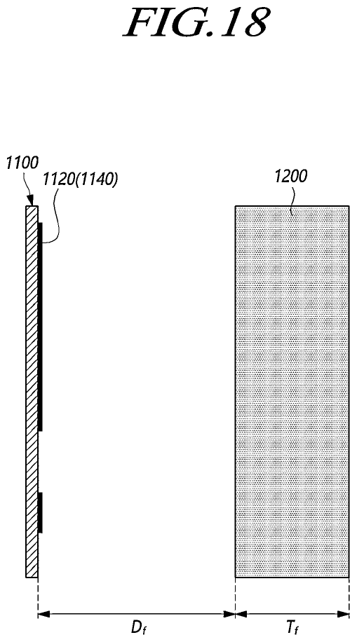

FIG. 17 is a conceptual plan view of a substrate body of a radar device according to an embodiment of the present disclosure, and FIG. 18 illustrates an arrangement relationship between a radome and a substrate body used in a radar device according to an embodiment of the present disclosure.

According to an embodiment of the present disclosure, a flat radome may be used in a radar device including a substrate body to or on which a transmission antenna, a reception antenna and a signal processing chip are mounted, and may be spaced apart from the substrate body to protect the substrate body

A value of the first design parameter and a value of the second design parameter of the radome may be set such that a difference value between a first determination parameter in the presence of the radome and a first determination parameter in the absence of the radome, a difference value between a second determination parameter in the presence of the radome and a second determination parameter in the absence of the radome, and a difference value between a third determination parameter in the presence of the radome and a third determination parameter in theabsence of the radome are within a first threshold range, a second threshold range, and a third threshold range, respectively.

The first design parameter may be the thickness T of the radome, and the second design parameter may be the distance D between one side of the radome and the substrate body. The first determination parameter may be a central peak power P0 of the 2-way transmission/reception signal used in the radar device, the second determination parameter may be a beam width of the 2-way transmission/reception signal, and the third determination parameter may be a beam error within a specific field of view.

The difference values may include a first difference value, a second difference value and a third difference value. The first difference value, the second difference value and the third difference value may be difference values of the first determination parameter, the second determination parameter and the third determination parameter between a first value in the case that the radome is present and a second value in the case that the radome is not present. The first difference value, the second difference value and the third difference value may be determined while changing the values of the first design parameter and the second design parameter within a first design range and a second design range, respectively.

In addition, the threshold ranges may include first to third threshold ranges. For instance, the first threshold range may be 0 to 0.3 dB, the second threshold range may be 0 to 0.3 degrees, and the third threshold range may be 0 to 0.7 dB, but is not limited thereto.

In addition, referring to FIGS. 17 and 18, a radar device according to an embodiment of the present disclosure may include one or more transmission antennas 1120 and one or more reception antennas 1140, a transceiver 1150 configured to transmit a transmission signal through the transmission antenna 1120 and receive a reception signal reflected from an object or target through the reception antenna 1140, a signal processor 1160 configured to process the reception signal to acquire information related to the object or target, a substrate body 1100 to or on which the transmission antenna 1120, the reception antenna 1140, the transceiver 1150, and the signal processor 1160 are mounted, and a radome 1200 disposed to be spaced apart from the substrate body 1100 by a predetermined distance.

A plurality of transmission antennas 1140 and receiving antennas 1120 may be provided, and each antenna may have a structure in which two, four, or six array antennas extend to one side while having one feeding point, but is not limited thereto.

In the embodiments of the present disclosure, each antenna will be described as an example of a structure in which two array antennas extend to one side while having one feed point.

In this case, each array antenna constituting the transmission antenna and the receiving antenna may be composed of a plurality of elements or patches connected to the output line of the distributor, and may extend in an upward direction (upward among vertical directions) from a feed port connected to a chip including a controller or an input port of a distributor as a starting point.

According to an embodiment of the present disclosure, the transmission antenna 1120 may include a short-range transmission antenna (SRR, Tx) for short-range detection and a long-range transmission antenna (LRR, Tx) for mid-to-long-range detection.

The short-range transmission antenna may comprise one channel (single antenna), and the long-range transmission antenna may comprise six channels. For example, the short-range transmission antenna may be expressed as a Tx_SRR antenna, and the long-range transmission antenna may include 6 antennas of TX_LRR #1 to #6.

In addition, the reception antenna 1140 may be composed of 8 channels. For instance, the reception antenna 1140 may include eight individual receiving antennas Rx #1 to #8.

In particular, according to an embodiment of the present disclosure, at least one of the plurality of reception antennas may be offset from the other reception antennas by a predetermined distance d in the vertical direction.

In the embodiment of FIG. 17, the eighth reception antenna Rx #8 among the eight reception antennas may be offset upward by a predetermined offset distance d with respect to the remaining reception antennas Rx #1 to #7 in the vertical direction.

The vertical direction may be a direction in which the array antenna of each antenna extends.

The vertical information related to the object or target, for example, elevation angle or height of the object or target can be acquired from the transmission signal and the reception signal by using the offset structure of the reception antenna as described above.

Specifically, there may be a phase difference according to a vertical offset between the reception signal received from the receiving antennas Rx #1 to #7 and the reception signal received from the receiving antenna Rx #8, and the vertical information such as elevation angle or height of the object or target can be obtained using this phase difference.

The transceiver 1150 of the radar device according to an embodiment of the present disclosure may include a transmitter and a receiver, and the transmitter may include an oscillator configured to supply a signal to each transmission antenna to generate a transmission signal. The oscillator may include, for example, but not limited to, a voltage-controlled oscillator (VCO).

The receiver included in the transceiver 1150 may include a low noise amplifier (LNA) for low-noise amplification of the reflection signal received through the reception antenna 1140, and a mixer for mixing the low-noise amplified reception signal, an amplifier configured to amplify the mixed reception signal, and an analog digital converter (ADC) configured to generate reception data by digitally converting the amplified reception signal.

The signal processor 1160 of the radar device according to an embodiment of the present disclosure may detect one or more peak signals of the object or target by Fourier transforming the reception signal received from the reception antenna 1140, and may determine a distance or a range R to the object target using frequency components included in each peak signal.

The transmission signal may include a plurality of fast chirp signals. The signal processor 1160 may perform first Fourier transform (1st FFT) on the reception signal to obtain a time component according to a range, and may generate a range-Doppler map representing speed information according to the range by performing a second Fourier transform (2nd FFT).

The signal processor 1160 may include a first processing unit and a second processing unit. The first processing unit, as a pre-processor for the second processing unit, may acquire transmission data and reception data, control the generation of the transmission signal in the oscillator based on the acquired transmission data, synchronize the transmission data and the reception data, and perform the frequency-conversion on the transmission data and the reception data.

The second processing unit may be a post-processor configured to perform actual processing operations using the processing result of the first processing unit. For example, the second processing unit may perform a CFAR (Constant False Alarm Rate) calculations, tracking calculations, target selection calculations based on the reception data frequency-converted by the first processing unit. In addition, the second processing unit may calculate height information of the object target according to the method described above.

The first processing unit may perform frequency conversion after data buffering the acquired transmission data and the acquired reception data in a unit sample size that can be processed per cycle. For example, the frequency conversion performed by the first processing unit may be implemented by using a Fourier transform such as a Fast Fourier Transform (FFT).

The second processing unit may perform a second Fourier transform on a first Fourier transform (FFT) signal performed by the first processing unit, and the second Fourier transform may be, for example, but not limited to, a Discrete Fourier Transform (DFT), in particular, a chirp-discrete Fourier transform (Chirp-DFT).

The second processing unit may acquire frequency values corresponding to the number of times corresponding to the second Fourier transform length K through the second Fourier transform such as Chirp-DFT. The second processing unit may detect an object by calculating the beat frequency with the greatest power during each chirp period based on the obtained frequency value, and obtaining speed information and distance information of the object based on the calculated beat frequency.

The signal processor 1160 may be expressed by other terms such as a controller, and may be implemented in the form of a digital signal processor (DSP).

Meanwhile, the radar device may be classified into a pulse type, a frequency modulation continuous wave (FMCW) type, a frequency shift keying (FSK) type, or the like, depending on the signal type.

The FMCW-type radar may use a chirp signal or a ramp signal, which is a signal of which frequency increases with time, and may calculate information on the target or object using a time difference between a transmission wave and a reception wave and a Doppler frequency shift.

In addition, the radar device according to an embodiment of the present disclosure may utilize a MIMO antenna system to implement vertical and horizontal detection accuracy or resolution.

More specifically, in the MIMO system, each transmission antenna may transmit signals having independent waveforms which are distinguished from each other. That is, each transmission antenna may transmit a signal of an independent waveform distinct from other transmission antennas, and each reception antenna may distinguish a transmission antenna that has transmitted a transmission signal corresponding to a reflection signal reflected from an object or target by using different waveforms of the signals.

The radar device or radar system used in an embodiment of the present disclosure may include at least one radar sensor unit, for example, a front radar sensor mounted on the front of the vehicle, a rear radar sensor mounted on the rear of the vehicle, and a side or side-rear detection radar sensors mounted on each side of the vehicle.

The radar sensor or radar system may analyze a transmission signal and a reception signal to process data, thereby detecting information related to an object or target, and may include an electronic or control unit (ECU) or processor for this purpose. Data transmission or signal communication from the radar sensor to the ECU may be performed using a communication link such as a vehicle network bus or the like.

In addition, in the above embodiment, a vehicle radar device has been described as an example, but the present disclosure is not limited thereto and may be applied to radar devices used in other fields.

Meanwhile, as shown in FIG. 18, in the radar device according to an embodiment of the present disclosure, the thickness Tf of the radome 1200 may be determined by the final value of the first design parameter determined according to some embodiments of the method of designing the radome described above.

In addition, the distance Df between the radome 1200 and the substrate body 1100 may be determined by the final value of the second design parameter determined according to certain embodiments of the method of designing the radome described above.

That is, the radome 1200 according to an embodiment of the present disclosure may be manufactured based on the first design parameter T and the second design parameter D which are set so that the differences of the first determination parameter (e.g. Center Peak Power such as P0), the second determination parameter (e.g. Beamwidth such as 20 dB Beamwidth) and the third determination parameter (e.g. Beam Error such as RMSE) between a case of the presence of the radome and a case of absence of the radome are within the threshold ranges.

The radome and the radar device using the radome according to some embodiments of the present disclosure can minimize the signal distortion caused by the radome. Therefore, it is possible to reduce the performance degradation of the radar device due to the radome, thereby improving the detection performance of the radar device.

It should be noted that although all or some of the configurations or elements included in one or more of the embodiments described above have been combined to constitute a single configuration or component or operated in combination, the present disclosure is not necessarily limited thereto. That is, within the scope of the object or spirit of the present disclosure, all or some of the configurations or elements included in the one or more of the embodiments may be combined to constitute one or more configurations or components or operated in such combined configuration(s) or component (s). Further, each of the configurations or elements included in one or more of the embodiments may be implemented by an independent hardware configuration; however, some or all of the configurations or elements may be selectively combined and implemented by one or more computer program(s) having one or more program module (s) that perform some or all functions from one or more combined hardware configuration(s). Codes or code segments constituting the computer program(s) may be easily produced by those skilled in the art. As the computer programs stored in computer-readable media are read and executed by a computer, embodiments of the present disclosure can be implemented. The media for storing computer programs may include, for example, a magnetic storing medium, an optical recording medium, and a carrier wave medium.

Further, unless otherwise specified herein, terms ‘include’, ‘comprise’, ‘constitute’, ‘have’, and the like described herein mean that one or more other configurations or elements may be further included in a corresponding configuration or element. Unless otherwise defined herein, all the terms used herein including technical and scientific terms have the same meaning as those understood by those skilled in the art. The terms generally used such as those defined in dictionaries should be construed as being the same as the meanings in the context of the related art and should not be construed as being ideal or excessively formal meanings, unless otherwise defined herein.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A method for designing a radome spaced apart from a substrate body to which a transmission antenna, a reception antenna and a signal processing chip are mounted, the method comprising:
defining a first design parameter for designing the radome and a second design parameter for designing the radome;
defining a first determination parameter, a second determination parameter and a third determination parameter indicating distortion characteristics of a transmission signal or a reception signal caused by the radome;
while changing a value of the first design parameter of the radome within a first design range and a value of the second design parameter of the radome within a second design range, determining first, second and third difference values which are differences between first values of the first, second and third determination parameters in a case that the radome is present and second values of the first, second and third determination parameters in another case that the radome is not present, respectively; and
determining a final value of the first design parameter and a final value of the second design parameter when the first difference value, the second difference value and the third difference value are within a first threshold range, a second threshold range and a third threshold range, respectively.

2. The method of claim 1, wherein the first design parameter is a thickness of the radome, and the second design parameter is a distance between the radome and the substrate body.

3. The method of claim 2, wherein the first determination parameter is a central peak power of a 2-way transmission or reception signal defined by at least one of the transmission signal and the reception signal, the second determination parameter is a beam width of the 2-way transmission or reception and signal, the third determination parameter is a beam error within a field of view.

4. The method of claim 3, further comprising determining initial values of the first design parameter and the second design parameter based on a permittivity of material of the radome and a wavelength of the 2-way transmission or reception signal,
wherein the first design range and the second design range are determined based on the initial values of the first design parameter and the second design parameter.

5. The method of claim 4, wherein the initial value of the first design parameter is determined by an integer multiple of a half wavelength of the 2-way transmission or reception signal propagating inside the radome, and the initial value of the second design parameter is determined by an integer multiple of a half wavelength of the 2-way transmission or reception signal propagating in an air space between the radome and the substrate body.

6. The method of claim 5, wherein the first design range for the first design parameter is determined to be 0.69 to 1.06 times a wavelength of the 2-way transmission or reception signal propagating inside the radome, and the second design range for the second design parameter is determined to be 0.89 to 1.15 times a wavelength of the 2-way transmission or reception signal propagating in the air space between the radome and the substrate body.

7. The method of claim 3, wherein the second determination parameter is a 20 dB beam width of the 2-way transmission or reception signal, and the third determination parameter is a root mean square error (RMSE) of signal power at radiation angles of −40 degrees and +40 degrees.

8. The method of claim 7, wherein the first threshold range is 0 to 0.3 dB, the second threshold range is 0 to 0.3 degrees, and the third threshold range is 0 to 0.7 dB.

9. The method of claim 1, further comprising forming a database of the first difference value, the second difference value and the third difference value.

10. The method of claim 1, further comprising generating a first graph, a second graph and a third graph for the first difference value, the second difference value and the third difference value according to change to values of the first design parameter and the second design parameter, respectively.

11. A radome of a radar device,
wherein the radome is comprised in the radar device including a substrate body to which a transmission antenna, a reception antenna and a signal processing chip are mounted, and the radome is spaced apart from the substrate body,
wherein a value of a first design parameter for designing the radome and a value of a second design parameter for designing the radome are set such that a difference between a first determination parameter in presence of the radome and a first determination parameter in absence of the radome, a difference between a second determination parameter in the presence of the radome and a second determination parameter in the absence of the radome, and a difference between a third determination parameter in the presence of the radome and a third determination parameter in the absence of the radome are within threshold ranges, the first, second and third determination parameters indicating distortion characteristics of a transmission signal or a reception signal caused by the radome.

12. The radome of claim 11, wherein the first design parameter is a thickness of the radome, and the second design parameter is a distance between the radome and the substrate body.

13. The radome of claim 12, wherein the first determination parameter is a central peak power of a 2-way transmission or reception signal defined by at least one of the transmission signal and the reception signal, the second determination parameter is a beam width of the 2-way transmission or reception signal, and the third determination parameter is a beam error within a filed of view.

14. The radome of claim 13, wherein the second determination parameter is a 20 dB beam width of the 2-way transmission or reception signal, and the third determination parameter is a root mean square error (RMSE) of signal power at radiation angles of −40 degrees and +40 degrees.

15. The radome of claim 14, wherein the threshold ranges comprise:
a first threshold range for the first determination parameter, wherein the first threshold range is 0 to 0.3 dB;
a second threshold range for the second determination parameter, wherein the second threshold range is 0 to 0.3 degrees; and
a third threshold range for the third determination parameter, wherein the third threshold range is 0 to 0.7 dB.

16. A radar device comprising:
one or more transmission antennas and one or more reception antennas;
a transceiver configured to transmit a transmission signal through the one or more transmission antennas and receive a reception signal reflected from an object through the one or more reception antennas;
a signal processor configured to process the reception signal to acquire information related to the object;
a substrate body to which the one or more transmission antenna, the one or more reception antenna, the transceiver and and the signal processor are mounted; and
a radome disposed to be spaced apart from the substrate body,
wherein a value of a first design parameter for designing the radome and a value of a second design parameter of the radome for designing the radome are set such that a difference between a first determination parameter in presence of the radome and a first determination parameter in absence of the radome, a difference between a second determination parameter in the presence of the radome and a second determination parameter in the absence of the radome, and a difference between a third determination parameter in the presence of the radome and a third determination parameter in the absence of the radome are within threshold ranges, the first, second and third determination parameters indicating distortion characteristics of the transmission signal or the reception signal caused by the radome.

17. The radar device of claim 16, wherein the first design parameter is a thickness of the radome, and the second design parameter is a distance between the radome and the substrate body.

18. The radar device of claim 17, wherein the first determination parameter is a central peak power of a 2-way transmission or reception signal defined by at least one of the transmission signal and the reception signal, the second determination parameter is a beam width of the 2-way transmission or reception and signal, the third determination parameter is a beam error within a filed of view.

19. The radar device of claim 18, wherein the second determination parameter is a 20 dB beam width of the 2-way transmission or reception signal, and the third determination parameter is a root mean square error (RMSE) of signal power at radiation angles of −40 degrees and +40 degrees.

20. The radar device of claim 19, wherein the threshold ranges comprise:
a first threshold range for the first determination parameter, wherein the first threshold range is 0 to 0.3 dB;
a second threshold range for the second determination parameter, wherein the second threshold range is 0 to 0.3 degrees; and
a third threshold range for the third determination parameter, the third threshold range is 0 to 0.7 dB.

21. The radar device of claim 16, wherein the one or more transmission antennas include six long-range transmission antennas used in a mid-to-long-range detection mode and one short-range transmission antenna used in a short-range detection mode.

22. The radar device of claim 21, wherein the one or more reception antennas comprise eight receptions antennas, and at least one of the eight reception antennas is vertically offset from other of the eight reception antennas.
